(19) United States
(12) Patent Application Publication
(10) Pub. No.: US 2025/0233063 A1
(43) Pub. Date: Jul. 17, 2025

(54) SEMICONDUCTOR PACKAGE STRUCTURE AND METHOD FOR FORMING THE SAME

(71) Applicant: TAIWAN SEMICONDUCTOR MANUFACTURING COMPANY LTD., HSINCHU (TW)

(72) Inventors: CHUN-HAO LIN, TAINAN CITY (TW); YU-JEN WANG, KAOHSIUNG CITY (TW); WEI-TAO TSAI, TAINAN CITY (TW); KAI-YUN YANG, TAINAN CITY (TW); CHUN-HAO CHOU, TAINAN CITY (TW)

(21) Appl. No.: 18/413,079

(22) Filed: Jan. 16, 2024

(51) Int. Cl. H01L 23/498; H01L 23/48

(52) U.S. Cl. CPC H01L 23/49838; H01L 23/481; H01L 23/49822

(57) ABSTRACT

A semiconductor package structure includes a first semiconductor component, a second semiconductor component, a bonded structure, a first through-substrate via, a pad, and a conductive feature. The first semiconductor component includes a first substrate and a first interconnect structure electrically connecting the first through-substrate via to the pad. The first interconnect structure is disposed over a first side of the first substrate. The second semiconductor component includes a second substrate and a second interconnect structure. The first through-substrate via penetrates the first substrate from a second side to the first side. The second side is opposite to the first side. The pad is disposed over the second side of the first substrate. The conductive feature is disposed over the second side of the first substrate and between the first through-substrate via and the pad. The conductive feature is electrically connected to the first interconnect structure by the first through-substrate via.

### BACKGROUND

Greater densities of electronic components may be achieved by fabricating three-dimensional (3D) integrated circuit (IC) device structures. Some 3D device structures, such as wafer-on-wafer (WoW) structures, are formed by stacking and bonding multiple IC devices (i.e., chips) at a semiconductor wafer level. Such 3D bonded wafer device structures may provide improved integration density and other advantages, such as greater speeds and greater bandwidths, due to the decreased lengths of interconnects between the stacked chips.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 10 are partial cross-sectional views of various stages in a formation of a semiconductor package structure in accordance with aspects of the present disclosure in one or more embodiments.

FIGS. 11A to 20 are partial cross-sectional views of various stages in a formation of a semiconductor package structure in accordance with aspects of the present disclosure in one or more embodiments.

FIG. 21 is a flowchart representing a method for forming a semiconductor package structure in accordance with aspects of the present disclosure.

FIG. 22 is a flowchart representing a method for forming a semiconductor package structure in accordance with to aspects of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective test measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In a bonded wafer structure, such as a WoW structure, topmost metal lines needed be thick enough to reduce sheet resistance and prevent IR drop. However, such thick metal lines may cause an issue of warpage of the bonded wafer structure. The warpage issue may cause an undesired adverse effect on the bonding between the bonded wafers. To compensate for such issues, the thickness of the metal lines is reduced, but the bonded wafer structure then suffers from increased sheet resistance and from IR drop. This trade-off presents one of several challenges related to production of 3D package structures.

In accordance with to some embodiments, the present disclosure provides semiconductor package structures and methods of forming the semiconductor package structures, particularly WoW structures. In some embodiments, the semiconductor package structure has a scheme including metal lines with sufficient thickness to reduce sheet resistance and to prevent IR drop. The scheme of the semiconductor package structure also helps to reduce warpage and thus results in improved bonding performance.

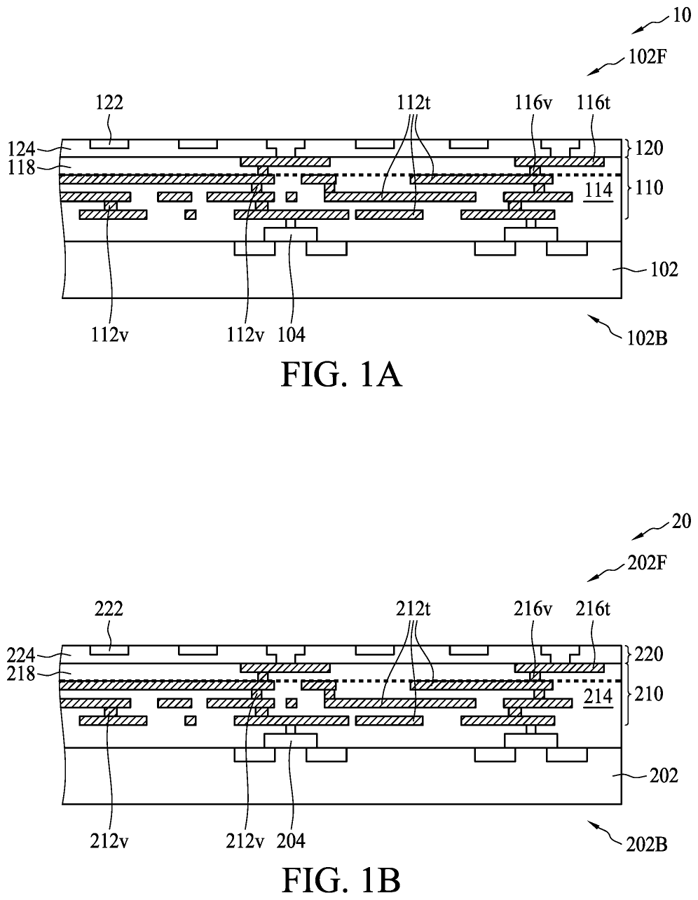

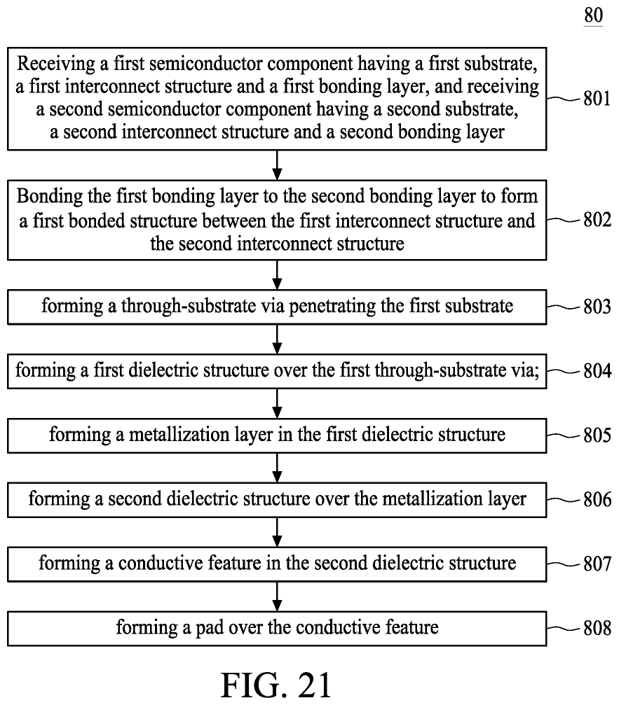

FIGS. 1A to 10 are partial cross-sectional views of various stages in a formation of a semiconductor package structure in accordance with aspects of the present disclosure in one or more embodiments. The corresponding operations are reflected schematically in a flowchart shown in FIG. 21.

Please refer to FIGS. 1A and 1B, which respectively illustrate a portion of a semiconductor component in accordance with embodiments of the present disclosure. In some embodiments, a semiconductor component 10 is received as shown in FIG. 1A, and a semiconductor component 20 is received as shown in FIG. 1B. The semiconductor component 10 may include a substrate 102 and a plurality of microelectronic elements 104 formed therein and thereon. The semiconductor component 20 may include a substrate 202 and a plurality of microelectronic elements 204 formed therein and thereon.

Each of the substrates 102 and 202 is defined to mean any construction including semiconductor materials, including, but not limited to, bulk silicon, a semiconductor wafer, a silicon-on-insulator (SOI) substrate, or a silicon germanium substrate. Other semiconductor materials including group III, group IV, and group V elements may also be used. Each of the substrate 102 and the substrate 202 may include an active surface on a first side (i.e., a front side) 102F, 202F and a second side (i.e., a back side) 102B, 202B opposite to the first side 102F, 202F. The substrates 102 and 202 may further include a plurality of isolation features (not shown), such as shallow trench isolation (STI) features or local oxidation of silicon (LOCOS) features formed therein. The isolation features may define and isolate active regions in the substrates 102 and 202. Each of the semiconductor components 10 and 20 includes the various microelectronic elements 104, 204. Examples of the various microelectronic elements 104 and 204 include transistors (e.g., metal-oxide-semiconductor field-effect transistors (MOSFET), complementary metal-oxide-semiconductor (CMOS) transistors, bipolar junction transistors (BJT), high-voltage transistors, high-frequency transistors, p-channel and/or n-channel field- effect transistors (PFETs/NFETs), etc.); resistors; diodes; capacitors; inductors; fuses; and other suitable elements. Various processes are performed to form the various microelectronic elements including deposition, etching, implantation, photolithography, annealing, and other suitable processes. The microelectronic elements 104 are interconnected to form an integrated circuit device, and the microelectronic elements 204 are interconnected to form an integrated circuit device. The integrated circuit device can be a logic device, a memory device (e.g., an SRAM), an RF device, an input/output (I/O) device, a system-on-chip (SoC) device, combinations thereof, and other suitable types of devices.

Each of the semiconductor components 10 and 20 may include inter-layer dielectric (ILD) layers (not shown) and a back-end-of-line (BEOL) interconnect structure 110, 210 electrically connected to the various microelectronic elements 104, 204. Further, the ILD layers of the BEOL interconnect structure 110 are disposed on the first side 102F of the substrate 102, and the ILD layers of the BEOL interconnect structure 210 are disposed over the first side 202F of the substrate 202. The ILD layers are formed over the substrates 102, 202 and fill spaces between the microelectronic elements 104, 204. In some embodiments, connecting structures such as contact plugs are formed in the ILD layers and electrically connect the various microelectronic elements 104, 204 to the overlying BEOL interconnect structures 110, 210.

The BEOL interconnect structure 110 includes metal lines 112t and vias 112v, which are formed in dielectric layers 114 (also referred to as inter-metal dielectrics (IMDs)). The BEOL interconnect structure 210 includes metal lines 212t and vias 212v, which are formed in IMDs 214. The metal lines 112t, 212t at a same level are collectively referred to herein as a metallization layer 112t, 212t. In accordance with some embodiments, each of the BEOL interconnect structures 110 and 210 includes a plurality of metallization layers 112t, 212t including the metal lines that are interconnected through the vias 112v, 212v. Formation of the metal lines 112t, 212t and the vias 112v, 212v in the dielectric layers 114, 214 may include single-damascene processes and/or dual-damascene processes. Those skilled in the art will realize the formation details of the BEOL interconnect structures 110 and 210.

The BEOL interconnect structure 110 includes a top metallization layer 116t, and vias 116v in a top dielectric layer 118, which is a topmost layer of several dielectric layers. The BEOL interconnect structure 210 includes a top metallization layer 216t and vias 216v in a top dielectric layer 218, which is a topmost layer of several dielectric layers. In accordance with some embodiments, the top dielectric layer 118, 218 is formed of a low-k dielectric material similar to a material of lower ones of the dielectric layers. In accordance with other embodiments, the top dielectric layer 118, 218 is formed of a non-low-k dielectric material, which may include silicon nitride, undoped silicate glass (USG), silicon oxide, or the like. In some embodiments, the top dielectric layer 118, 218 may include a multi-layer structure including, for example, two USG layers and a silicon nitride layer therebetween. The top metallization layers 116t and 216t may also be formed of copper or a copper alloy, and may have a dual-damascene structure or a single-damascene structure.

In some embodiments, a thickness of the top metallization layer 116t is greater than a thickness of each of the underlying metallization layers 112t, and a thickness of the top metallization layer 216t is greater than a thickness of each of the underlying metallization layers 212t. In some embodiments, the thickness of the top metallization layer 116t and the thickness of the top metallization layer 216t may be between approximately 8,000 angstroms and approximately 15,000 angstroms. In some embodiments, the thickness of the top metallization layer 116t and the thickness of the top metallization layer 216t may be approximately 12,500 angstroms. In some embodiments, the thickness of the top metallization layer 116t and the thickness of the top metallization layer 216t may be approximately 8,500 angstroms. In some embodiments, the thicknesses of the top metallization layers 116t and 216t are thick enough to efficiently reduce sheet resistance and prevent IR drop. However, warpages of the substrates 102, 202 caused by the top metallization layers 116t and 216t are mitigated by such thicknesses.

Still referring to FIGS. 1A and 1B, the semiconductor component 10 may include a bonding layer 120 formed over the BEOL interconnect structure 110, and the semiconductor component 20 may include a bonding layer 220 formed over the BEOL interconnect structure 210. Each of the bonding layers 120 and 220 includes a plurality of metallization features 122, 222 such as bonding pads disposed in at least a dielectric layer 124, 224. Some of the metallization features 122 are electrically connected to the BEOL interconnect structure 110, and some of the metallization features 222 are electrically connected to the BEOL interconnect structure 210. The dielectric layers 124 and 224 may include a suitable dielectric material, such as silicon oxide, silicon nitride, or like. In various embodiments, the dielectric layers 124 and 224 may include silicon oxynitride (SiOₓN_{y}). Other suitable dielectric materials may be within the contemplated scope of the disclosure. The metallization features 122 and 222 may include an electrically conductive material that may function as a bonding medium to mechanically bond the semiconductor component 10 to the semiconductor component 20, and may also enable electrical signals to be routed between the two semiconductor components 10 and 20. In various embodiments, the metallization features 122 and 222 may include a metal material, such as copper, a copper alloy, tungsten (W), aluminum (Al), an aluminum alloy, combinations thereof, or the like. Other suitable bonding materials are within the contemplated scope of the disclosure. In some embodiments, a barrier layer (not shown) composed of a suitable barrier material may be formed between the metallization features 122 and the dielectric layer 124, and between the metallization features 222 and the dielectric layer 224.

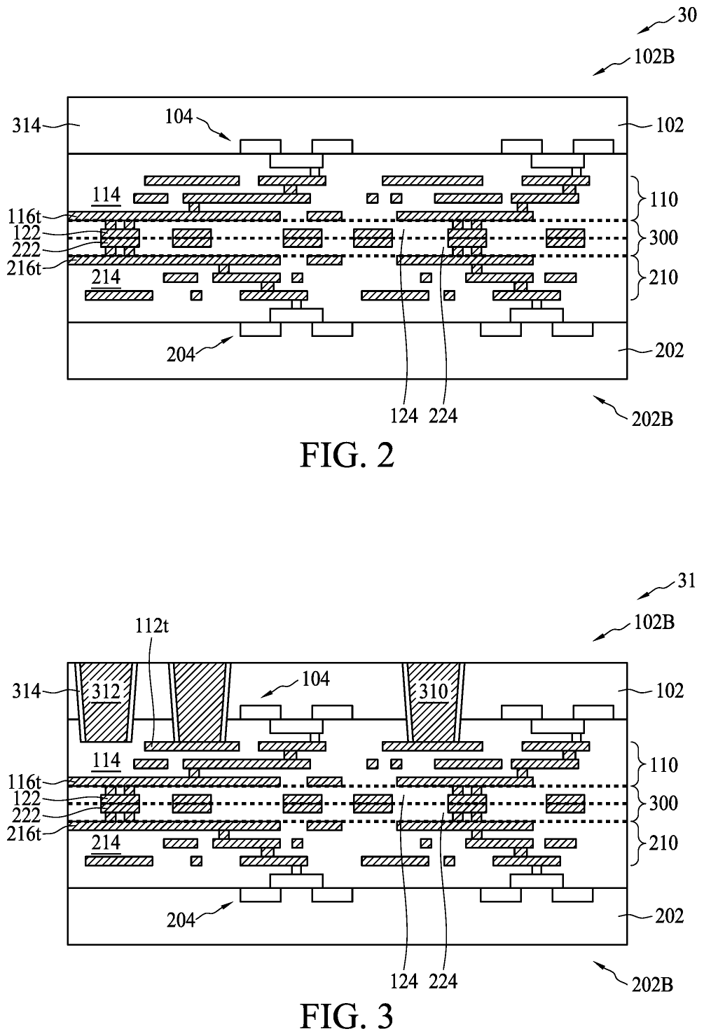

Referring to FIG. 2, in some embodiments, the semiconductor component 10 may be bonded to the semiconductor component 20 using a hybrid bonding technique. As shown in FIG. 2, in some embodiments, the surfaces of the semiconductor components 10 and 20 may optionally be pre-treated to promote surface activation (e.g., using a plasma treatment process). The semiconductor component 10 may be flipped (e.g., inverted) and stacked onto the semiconductor component 20 so that the bonding layer 120 of the semiconductor component 10 faces the bonding layer 220 of the semiconductor component 20. The semiconductor components 10 and 20 may be aligned such that the metallization features (i.e., the bonding pads) 122 of the semiconductor component 10 contact the corresponding metallization features (i.e., the bonding pads) 222 of the semiconductor component 20. The dielectric layers 124 and 224 of the semiconductor components 10 and 20 are bonded. In some embodiments, the stack of semiconductor components 10 and 20 may then be annealed at an elevated temperature. The bonding process may result in a diffusion bond forming between the metallization features 122 of the semiconductor component 10 and the corresponding metallization features 222 of the semiconductor component 20. Accordingly, the bonded dielectric layers 124 and 224 and the bonded metallization features 122 and 222 form a bonded structure 300 between the semiconductor component 10 and the semiconductor component 20. Further, the semiconductor components 10 and 20 are bonded by the bonded structure 300 to form an intermediate semiconductor package structure 30.

Referring to FIG. 3, in some embodiments, the second side 102B of the substrate 102 may optionally be thinned using a suitable process, such as mechanical grinding, chemical mechanical planarization (CMP), or by etching process. A plurality of through-substrate vias 310, 312 are formed. In some embodiments, the through-substrate vias 310, 312 may be formed by patterning the substrate 102 from the second side 102B to form openings (not shown) penetrating through the substrate 102. In some embodiments, the openings are formed in the substrate 102 and in a portion of the dielectric layer 114 of the BEOL interconnect structure 110. In some embodiments, a portion of the metallization layer 112t, such as the lowermost metallization layer 112t of the BEOL interconnect structure 110 may be exposed through a bottom of the opening. In other embodiments, a portion of the dielectric layer 114 may be exposed through a bottom of the opening.

Still referring to FIG. 3, in some embodiments, a liner 314 is formed on sidewalls of each of the openings that are formed in the substrate 102 and in the dielectric layer 114 of the BEOL interconnect structure 110. The liner 314 may include a suitable dielectric material, such as an oxide material (e.g., SiO₂) that may be deposited using a suitable deposition process. Other suitable dielectric materials for the liner 314 are within the contemplated scope of the disclosure. The liner 314 may help to maintain a voltage bias between the through-substrate vias 310 and 312 that are subsequently formed within the openings and the surrounding semiconductor material of the substrate 102.

Still referring to FIG. 3, in some embodiments, a layer of electrically conductive material is deposited over the second side 102B of the substrate 102 and within the openings, followed by a planarization process, such as a CMP process. In some embodiments, the electrically conductive material may include a metal material, such as copper (Cu), a copper alloy, aluminum (Al), an aluminum alloy, tungsten (W), combinations thereof, or the like. Subsequently, superfluous or excessive electrically conductive material is removed from the second side 102B of the substrate 102. The remaining electrically conductive material, located within the openings, forms the through-substrate vias 310 and 312. As shown in FIG. 3, the through-substrate vias 310 are in contact with and electrically connected to the lowermost metallization layer 112t of the BEOL interconnect structure 110. In such embodiments, an electrical connection between the first side 102F (i.e., the front side) and the second side 102B (i.e., the back side) of the substrate 102 may be formed by the BEOL interconnect structure 110 and the through-substrate vias 310.

In some embodiments, the through-substrate via 312 is in contact with the dielectric layer 114 of the BEOL interconnect structure 110. Such through-substrate via 312 may be electrically isolated from the through-substrate vias 310. In such embodiments, the through-substrate via 312 may be referred to as a dummy through-substrate via. In some embodiments, the dummy through-substrate via 312 is formed to help improve heat dissipation of an intermediate semiconductor package structure 31.

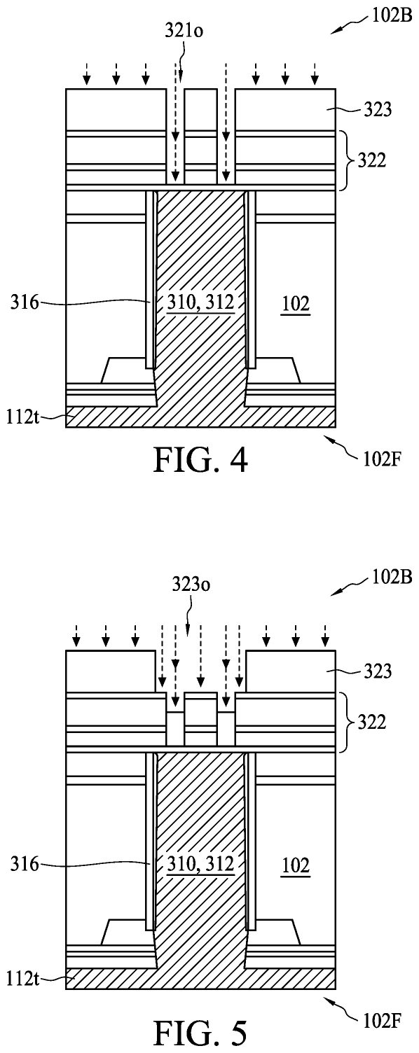

Please refer to FIGS. 4 to 8, which are partially enlarged views of the intermediate semiconductor package structure 31 at various stages in accordance with the present disclosure. In some embodiments, a redistribution layer (RDL) 320 (not shown in FIGS. 4 to 8) is formed over the second side 102B of the substrate 102 of the intermediate semiconductor package structure 31. In some embodiments, the forming of the RDL 320 includes further operations. Referring to FIG. 4, for example, a dielectric structure 322 may be formed over the second side 102B of the substrate 102. In some embodiments, the dielectric structure 322 may be a multilayered dielectric structure 322 that includes a plurality of dielectric layers including silicon oxide, silicon nitride, and silicon oxynitride, but the disclosure is not limited thereto. A patterned photoresist 321 may be formed over the multilayered dielectric structure 322. The patterned photoresist 321 includes plurality of openings 3210 for defining locations and sizes of via structures of the RDL 320. In some embodiments, the openings 3210 are transferred to the multilayered dielectric structure 322, as shown in FIG. 4.

Next, referring to FIG. 5, the patterned photoresist 321 is replaced with another patterned photoresist 323. The patterned photoresist 323 includes at least an opening 323o for defining a location and a size of a metallization layer of the RDL 320. The opening 323o may be transferred to the multilayered dielectric structure 322, as shown in FIG. 5. In some embodiments, the opening 323o is coupled to the openings 321o.

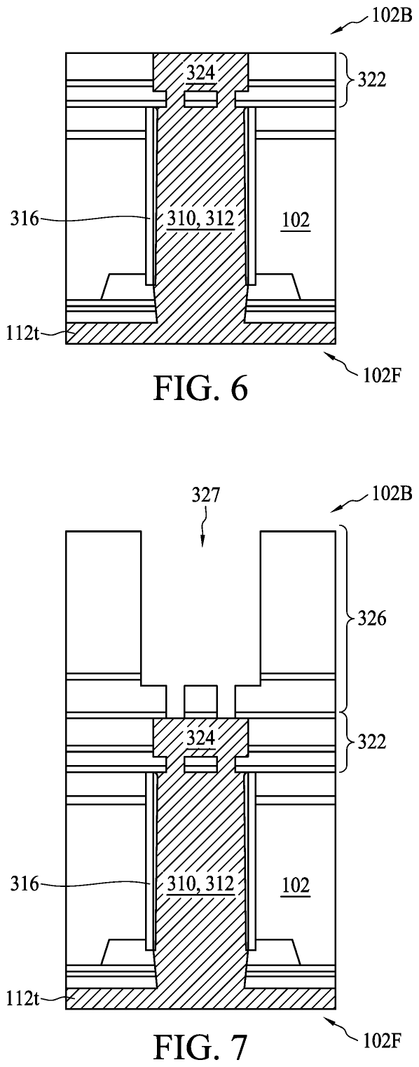

Referring to FIG. 6, a layer of electrically conductive material is deposited over the second side 102B of the substrate 102 and within the openings 321o and 323o, followed by a planarization process, such as a CMP process. Subsequently, superfluous or excessive portions of the electrically conductive material and dielectric materials are removed from the second side 102B of the substrate 102. The remaining electrically conductive material, located within the openings 311o and 323o, forms a metallization layer 324 in the multilayered dielectric structure 322. As shown in FIG. 6, the metallization layer 324 is coupled to and electrically connected to the through-substrate via 310, 312.

Referring to FIG. 7, a dielectric structure 326 is formed over the dielectric structure 322 and the metallization layer 324. In some embodiments, the dielectric structure 326 may be a multilayered dielectric structure 326 that includes a plurality of dielectric layers including silicon oxide, silicon nitride, and silicon oxynitride, but the disclosure is not limited thereto. In some embodiments, a thickness of the dielectric structure 326 is greater than a thickness of the dielectric structure 322. An opening 327 is formed in the dielectric structure 326. In some embodiments, portions of the metallization layer 324 may be exposed through a bottom of the opening 327.

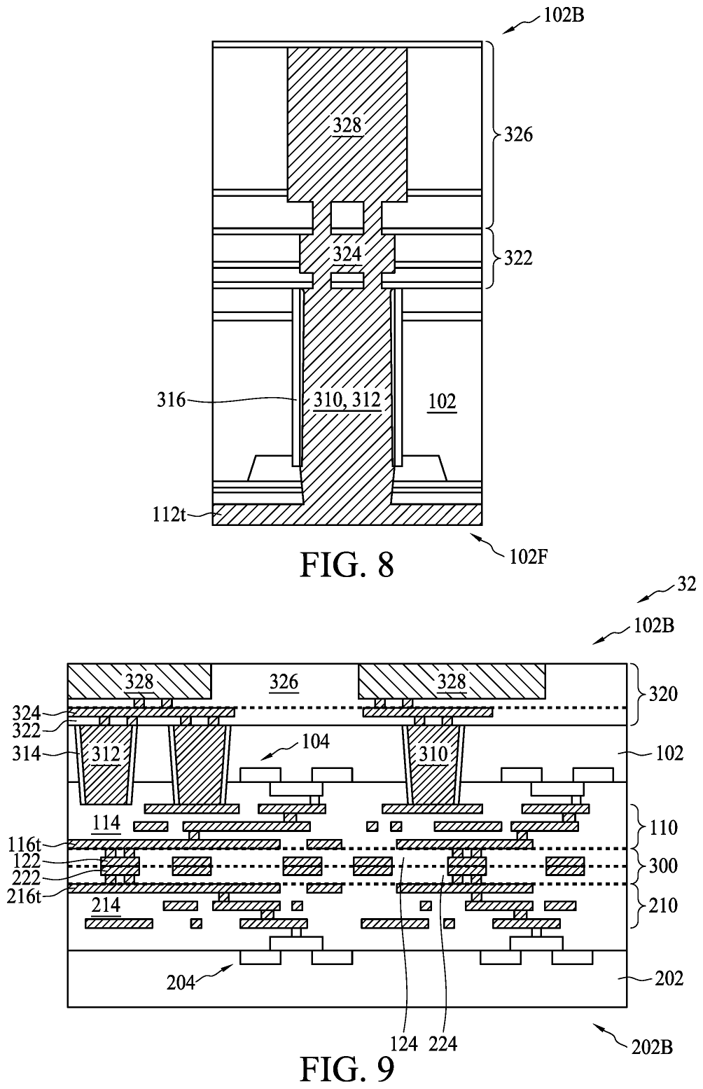

Referring to FIG. 8, a layer of electrically conductive material is deposited over the second side 102B of the substrate 102 and within the openings 327, followed by a planarization process, such as a CMP process. Subsequently, superfluous or excessive portions of the electrically conductive material and dielectric materials are removed from the second side 102B of the substrate 102. The remaining electrically conductive material, located within the openings, forms a conductive feature 328 in the dielectric structure 326. As shown in FIG. 8, the conductive feature 328 is coupled to and electrically connected to the metallization layer 324. In some embodiments, a thickness of the conductive feature 328 is greater than a thickness of the metallization layer 324. In some embodiments, the thickness of the metallization layer 324 may be less than 10,000 angstroms, and the thickness of the conductive feature 328 may be greater than 15,000 angstroms. For example but not limited thereto, the thickness of the metallization layer 324 may be approximately 8,500 angstroms, and the thickness of the conductive feature 328 may be approximately 35,000 angstroms.

Referring to FIG. 9, accordingly, the RDL 320 including at least the dielectric structures 322 and 326, the metallization layer 324 in the dielectric structure 322, and the conductive feature 328 in the dielectric structure 326 is obtained. As shown in FIG. 8, the conductive feature 328 is electrically connected to the BEOL interconnect structure 110 by the through-substrate vias 310. The thickness of the conductive feature 328 is greater than the thickness of the top metallization layer 116t, and greater than the thickness of the top metallization layer 216t. In some embodiments, the thickness of the conductive feature 328 is even greater than a sum of the thickness of the top metallization layer 116t of the BEOL interconnect structure 110 and the thickness of the top metallization layer 216t of the BEOL interconnect structure 210.

Still referring to FIG. 9, in some embodiments, the thickness of the conductive feature 328 is greater than any of the metallization layers 324 of the RDL 320, the metallization layers 112t, 116t of the BEOL interconnect structure 110, and the metallization layers 212t, 216t of the BEOL interconnect structure 210. Accordingly, the conductive feature 328 is thick enough to efficiently reduce sheet resistance and prevent IR drop. Further, because the conductive feature 328 is formed over the second side 102B (i.e., the back side) of the substrate 102, the warpage effect on the elements over the first side 102F (i.e., the front side) of the substrate 102 is mitigated. Thus, negative effect on to the bonding performance of the bonded structure 300 is mitigated.

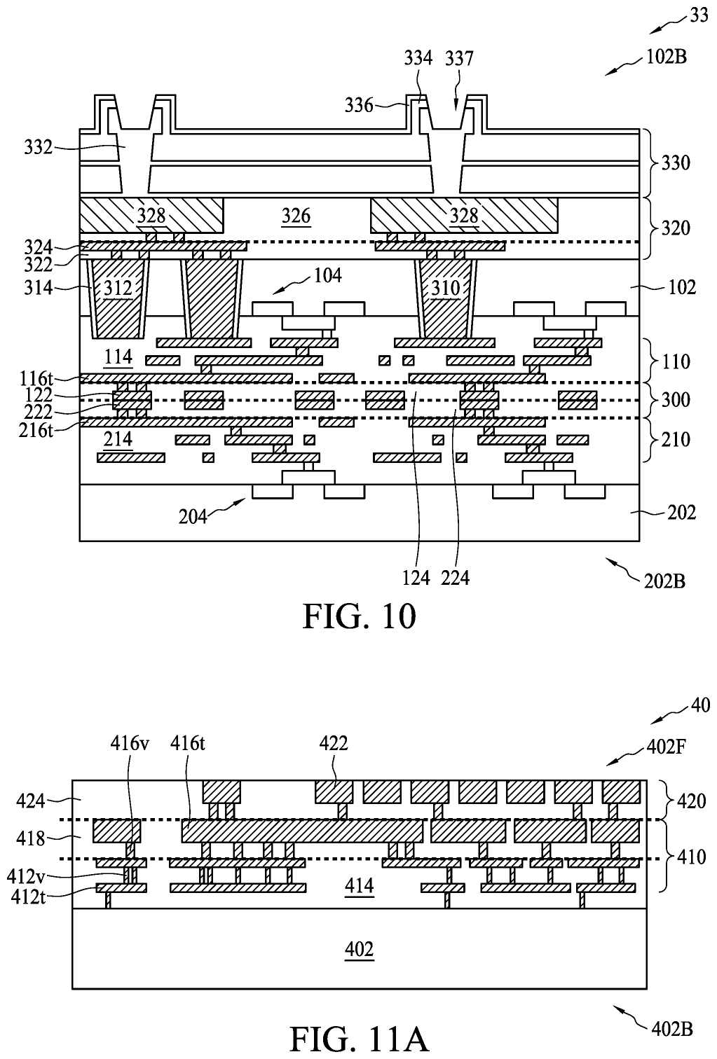

Referring to FIG. 10, in some embodiments, a dielectric structure 330 is formed over the RDL 320 on the second side 102B of the substrate 102. The dielectric structure 330 may be a multilayered dielectric structure. In some embodiments, the dielectric structure 330 may include dielectric layers including silicon oxide and silicon nitride. Other suitable dielectric materials are within the contemplated scope of the disclosure. The dielectric structure 330 may be a passivation structure for protection against stress and/or moisture. After the forming of the dielectric structure 330, a plurality of openings (not shown) are formed in the dielectric structure 330 to expose upper surfaces of the conductive features 328. An electrically conductive material is subsequently deposited over the upper surface of the dielectric structure 330 and within the openings. The electrically conductive material may contact the exposed surfaces of the conductive features 328 at a bottom of each of the openings. In various embodiments, the electrically conductive material may include a metal material, such as Cu, a copper alloy, Al, an aluminum alloy, W, or a combination thereof. Other electrically conductive materials are within the contemplated scope of the disclosure. In some embodiments, the electrically conductive material is patterned to form a plurality of pads 332 in and over the dielectric structure 330. As shown in FIG. 10, the pads 332 are in contact with and electrically connected to the conductive features 328. In some embodiments, a thickness of the pad 332 is greater than the thickness of the conductive feature 328.

Sill referring to FIG. 10, in some embodiments, a dielectric layer 334 and a dielectric layer 336 are sequentially formed over the pads 332 and the dielectric structure 330. In some embodiments, the dielectric layers 334 and 336 are conformally formed over the pads 332 and the dielectric structure 330. In some embodiments, both the dielectric layer 334 and the dielectric layer 336 serve as passivation layers for protection against stress and/or moisture. In some embodiments, the dielectric layer 334 and the dielectric layer 336 may include different materials. For example but not limited thereto, the dielectric layer 334 may include oxide material, such as silicon oxide, and the dielectric layer 336 may include nitride material, such as silicon nitride. Other suitable dielectric materials are within the contemplated scope of the disclosure.

Still referring to FIG. 10, in some embodiments, portions of the dielectric layers 334 and 336 are removed to form openings 337 exposing upper surfaces of the pads 332. In some embodiments, the dielectric layers 334 and 336 may remain over sidewalls and peripheral regions of upper surfaces of the pads 332. The exposed upper surfaces of the pads 332 can be coupled to external elements.

Accordingly, a semiconductor package structure 33 is obtained. The semiconductor package structure 33 includes the conductive features 328 disposed between the pads 332 and the through-substrate vias 310, 312. Further, the pads 332 are electrically connected to the through-substrate vias 310, 312 by the conductive features 328 of the RDL 320. In some embodiments, communications between external elements, the substrate 102 and the substrate 202 are enabled by the BEOL interconnect structure 210, the bonded structure 300, the BEOL interconnect structure 110, the through-substrate vias 310, the RDL 320 and the pads 332. In some embodiments, the conductive features 328 of the RDL 320 over the second side 102B of the substrate 102 are thick enough to reduce sheet resistance and prevent IR drop. Further, because the thick conductive features 328 are disposed on the second side 102B (i.e., the back side) of the substrate 102, the warpage effect on the devices over the first side 102F (i.e., the front side) of the substrate 102 is mitigated. Thus, negative effect on to the bonding performance of the bonded structure 300 of the semiconductor package structure 33 is mitigated.

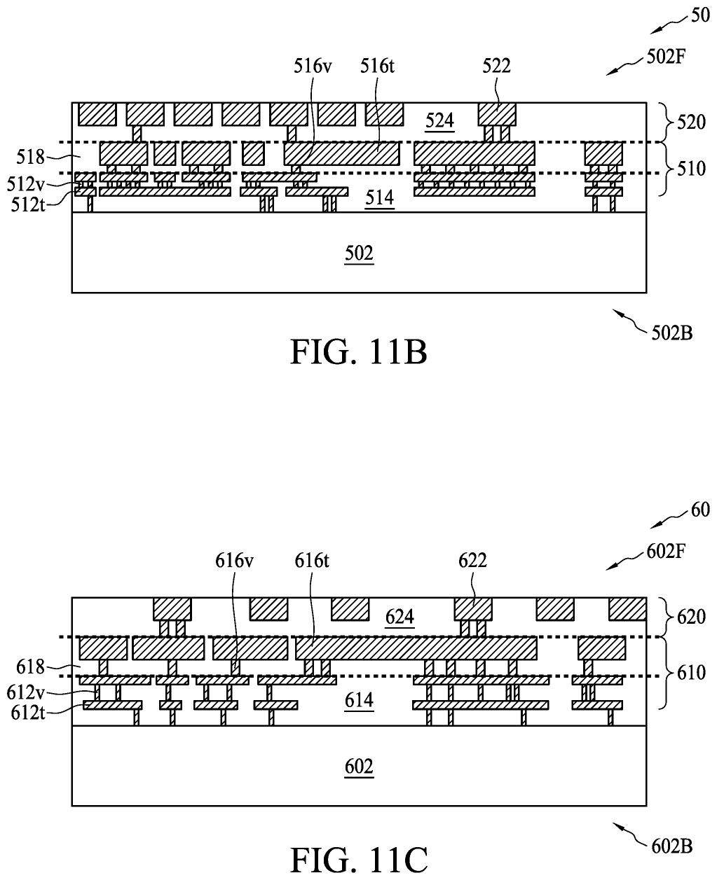

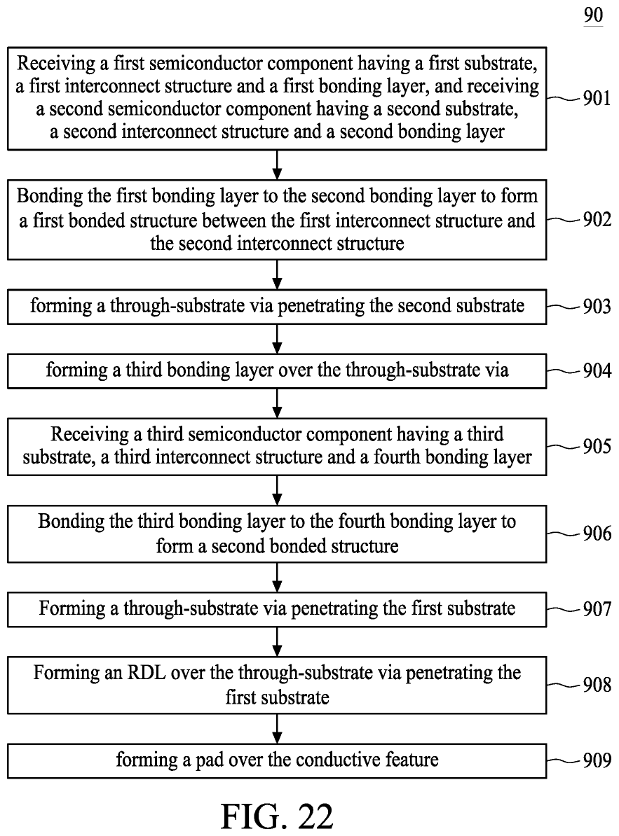

FIGS. 11A to 20 are partial cross-sectional views of various stages in a formation of a semiconductor package structure in accordance with aspects of the present disclosure in one or more embodiments. The corresponding operations are reflected schematically in a flowchart shown in FIG. 22.

Please refer to FIGS. 11A, 11B and 11C, which respectively illustrate a portion of a semiconductor component in accordance with embodiments of the present disclosure. In some embodiments, a semiconductor component 40 is received as shown in FIG. 11A, a semiconductor component 50 is received as shown in FIG. 11B, and a semiconductor component 60 is received as shown in FIG. 11C. The semiconductor component 40 may include a substrate 402 and a plurality of microelectronic elements (not shown) formed therein and thereon, the semiconductor component 50 may include a substrate 502 and a plurality of microelectronic elements (not shown) formed therein and thereon, and the semiconductor component 60 may include a substrate 602 and a plurality of microelectronic elements (not shown) formed therein and thereon.

Materials of the substrates 402, 502 and 602 may be similar to the materials described above; therefore, such details are omitted for brevity. Each of the substrates 402, 502 and 602 may include an active surface on a first side (i.e., a front side) 402F, 502F and 602F, and a second side (i.e., a back side) 402B, 502B and 602B opposite to the first side 402F, 502F and 602F. The substrates 402, 502 and 602 may further include a plurality of isolation features (not shown) for defining and isolating active regions in the substrates 402, 502 and 602. Each of the semiconductor components 40, 50 and 60 includes various microelectronic elements (not shown). The microelectronic elements are interconnected to form various integrated circuit devices. For example, the semiconductor component 40 may include deep trench capacitors (DTC), and thus is referred to as a DTC component. The semiconductor component 50 may include logic devices, and thus is referred to as a logic component. The semiconductor component 60 may include dynamic random-access memory (DRAM), and thus is referred to as a memory component. It should be noted that the semiconductor components 40, 50 and 60 can include various devices that are not limited to the examples mentioned above.

Each of the semiconductor components 40, 50 and 60 may include ILD layers (not shown) and a BEOL interconnect structure 410, 510, 610 electrically connected to the various microelectronic elements. Further, connecting structures such as contact plugs are formed in the ILD layers and electrically connect the various microelectronic elements to the overlying BEOL interconnect structures 410, 510, 610.

The BEOL interconnect structure 410 includes metal lines 412t and vias 412v formed in IMDs 414, the BEOL interconnect structure 510 includes metal lines 512t and vias 512v formed in IMDs 514, and the BEOL interconnect structure 610 includes metal lines 612t and vias 612v formed in IMDs 614. As mentioned above, the metal lines at a same level are collectively referred to herein as a metallization layer. In accordance with some embodiments, each of the BEOL interconnect structures 410, 510 and 610 includes a plurality of metallization layers 412t, 512t and 612t including the metal lines that are interconnected through the vias 412v, 512v and 612v.

The BEOL interconnect structure 410 includes a top metallization layer 416t, and vias 416v in a top dielectric layer 418, which is a topmost layer of several dielectric layers. The BEOL interconnect structure 510 includes a top metallization layer 516t and vias 516v in a top dielectric layer 518, which is a topmost layer of several dielectric layers. The BEOL interconnect structure 610 includes a top metallization layer 616t and vias 616v in a top dielectric layer 618, which is a topmost layer of several dielectric layers. In some embodiments, a thickness of the top metallization layer 416t is greater than a thickness of each of the underlying metallization layers 412t, a thickness of the top metallization layer 516t is greater than a thickness of each of the underlying metallization layers 512t, and a thickness of the top metallization layer 616t is greater than a thickness of each of the underlying metallization layers 612t. A range of the thicknesses of the top metallization layers 416t, 516t and 616t may be similar to that of the top metallization layers 116t and 216t; therefore, such details are omitted. In some embodiments, the thicknesses of the top metallization layers 416t, 516t and 616t may be similar. In other embodiments, the thicknesses of the top metallization layers 416t, 516t and 616t may be different. As mentioned above, the thicknesses of the top metallization layers 416t, 516t and 616t are sufficient to efficiently reduce sheet resistance and to prevent IR drop. In addition, warpage caused to the substrates 402, 502 and 602 by the top metallization layers 416t, 516t and 616t is mitigated by such thicknesses.

Still referring to FIGS. 11A, 11B and 11C, the semiconductor component 40 may include a bonding layer 420 formed over the BEOL interconnect structure 410, the semiconductor component 50 may include a bonding layer 520 formed over the BEOL interconnect structure 510, and the semiconductor component 60 may include a bonding layer 620 formed over the BEOL interconnect structure 610. Each of the bonding layers 420, 520 and 620 includes a plurality of metallization features 422, 522, 622 such as bonding pads disposed in at least a dielectric layer 424, 524, 624. Some of the metallization features 422 are electrically connected to the BEOL interconnect structure 410, some of the metallization features 522 are electrically connected to the BEOL interconnect structure 510, and some of the metallization features 622 are electrically connected to the BEOL interconnect structure 610. The metallization features 422, 522 and 622 may include an electrically conductive material that may function as a bonding medium to mechanically bond the semiconductor components 40, 50, 60 to each other, and that may also enable electrical signals to be routed between the three semiconductor components 40, 50 and 60.

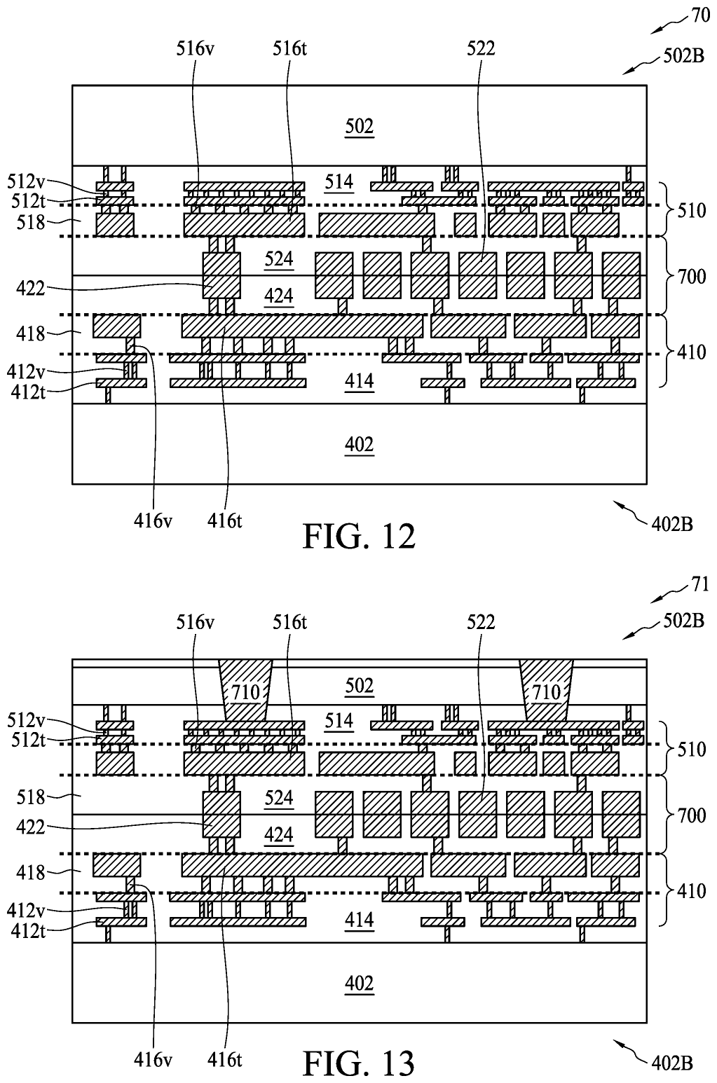

Referring to FIG. 12, in some embodiments, the semiconductor component 50 may be bonded to the semiconductor component 40 using a hybrid bonding technique. As shown in FIG. 12, the semiconductor component 50 may be flipped (e.g., inverted) and stacked onto the semiconductor component 40 so that the bonding layer 520 of the semiconductor component 50 faces the bonding layer 420 of the semiconductor component 40. The semiconductor components 40 and 50 may be aligned such that the metallization features (i.e., the bonding pads) 522 of the semiconductor component 50 contact the corresponding metallization features (i.e., the bonding pads) 422 of the semiconductor component 40. The dielectric layers 424 and 524 of the semiconductor components 40 and 50 are bonded, and the metallization features 422 and 522 of the semiconductor components 40 and 50 are bonded. Accordingly, the bonded dielectric layers 424 and 524 and the bonded metallization features 422 and 522 form a bonded structure 700 between the semiconductor component 40 and the semiconductor component 50. Further, the semiconductor components 40 and 50 are bonded by the bonded structure 700 to form an intermediate semiconductor package structure 70.

Referring to FIG. 13, in some embodiments, the second side 502B of the substrate 502 may optionally be thinned. A plurality of through-substrate vias 710 are formed. In some embodiments, operations for forming the through-substrate vias 710 may be similar to the operations for forming the through-substrate vias 310 and 312; therefore, such details are omitted for brevity. As shown in FIG. 13, the through-substrate via 710 is in contact with and electrically connected to the lowermost metallization layer 512t of the BEOL interconnect structure 510. In such embodiments, an electrical connection between the first side 502F (i.e., the front side) and the second side 502B (i.e., the back side) of the substrate 502 may be formed by the BEOL interconnect structure 510 and the through-substrate vias 710.

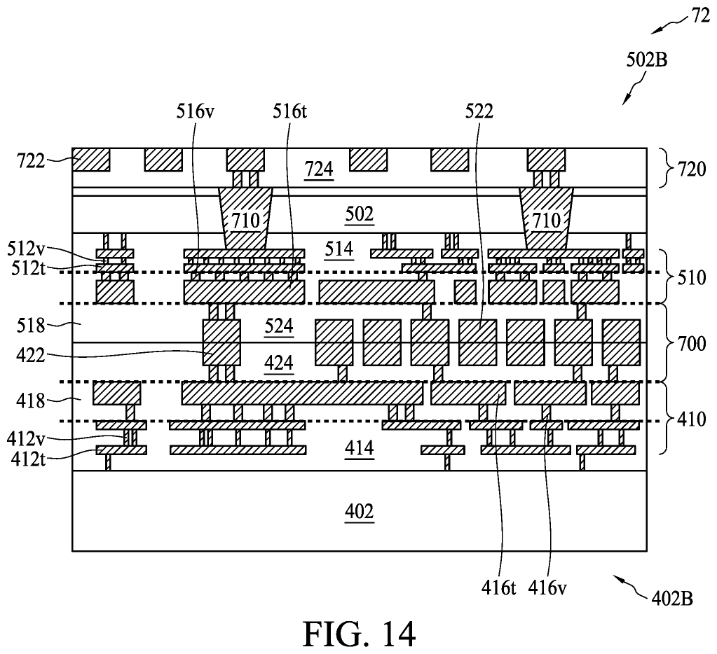

Referring to FIG. 14, in some embodiments, a bonding layer 720 is formed over the second side 502B of the substrate 502. The bonding layer 720 includes a plurality of metallization features 722, such as bonding pads, disposed in at least a dielectric layer 724. Further, some of the metallization features 722 are electrically connected to the BEOL interconnect structure 510 through the through-substrate vias 710. Accordingly, an intermediate semiconductor package structure 72 is obtained.

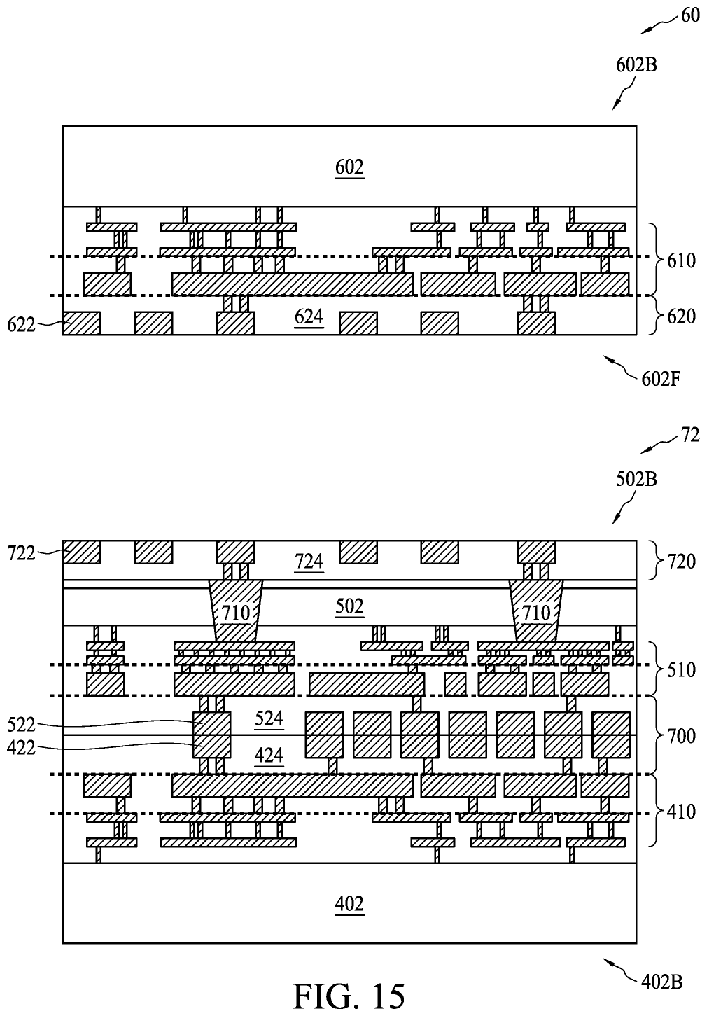

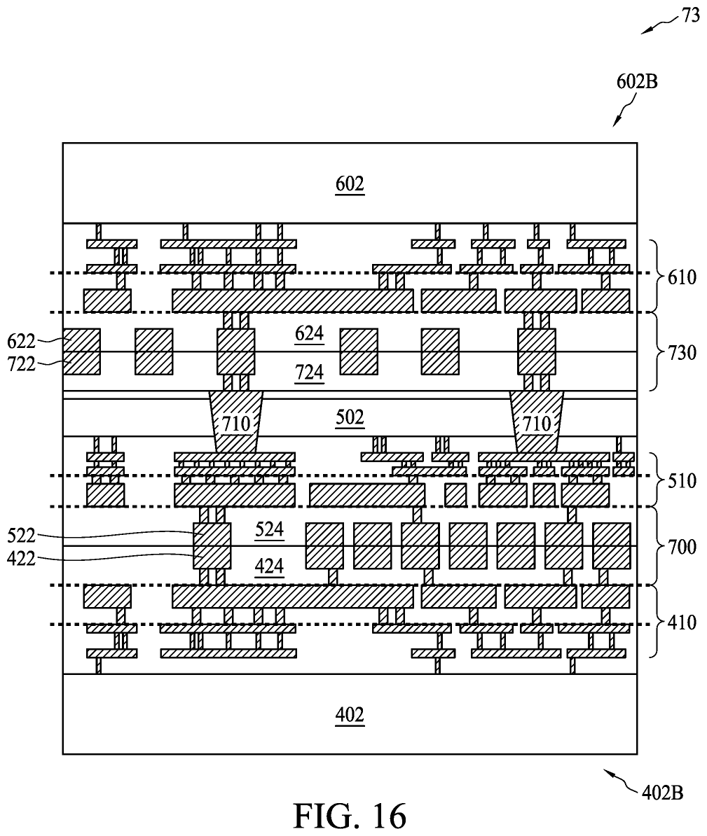

Referring to FIGS. 15 and 16, in some embodiments, the semiconductor component 60 may be bonded to the intermediate semiconductor package structure 72 using a hybrid bonding technique. As shown in FIG. 15, the semiconductor component 60 may be flipped (e.g., inverted) and stacked onto the intermediate semiconductor package structure 72 so that the bonding layer 620 of the semiconductor component 60 faces the bonding layer 720. As shown in FIG. 16, the metallization features (i.e., the bonding pads) 622 of the semiconductor component 60 contact the corresponding metallization features (i.e., the bonding pads) 722 of the bonding layer 720. The dielectric layers 624 and 724 are bonded, and the metallization features 622 and 722 are bonded. Accordingly, a bonded structure 730 is formed and an intermediate semiconductor package structure 73 is obtained, as shown in FIG. 16.

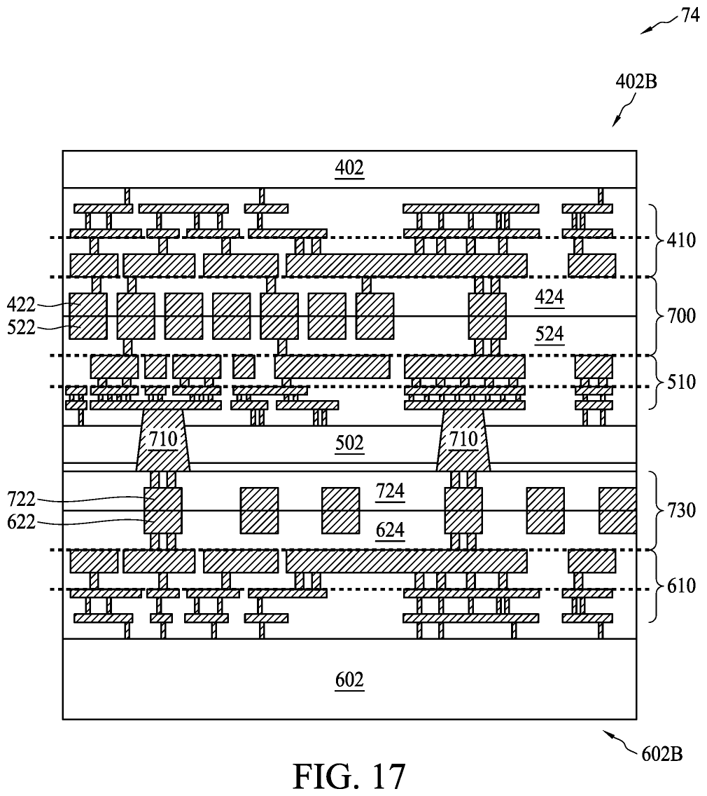

Referring to FIG. 17, the intermediate semiconductor package structure 73 is flipped. Further, the substrate 402 is thinned from the second side 402B using a suitable process, such as mechanical grinding, chemical mechanical planarization (CMP), or an etching process to form an intermediate semiconductor package structure 74.

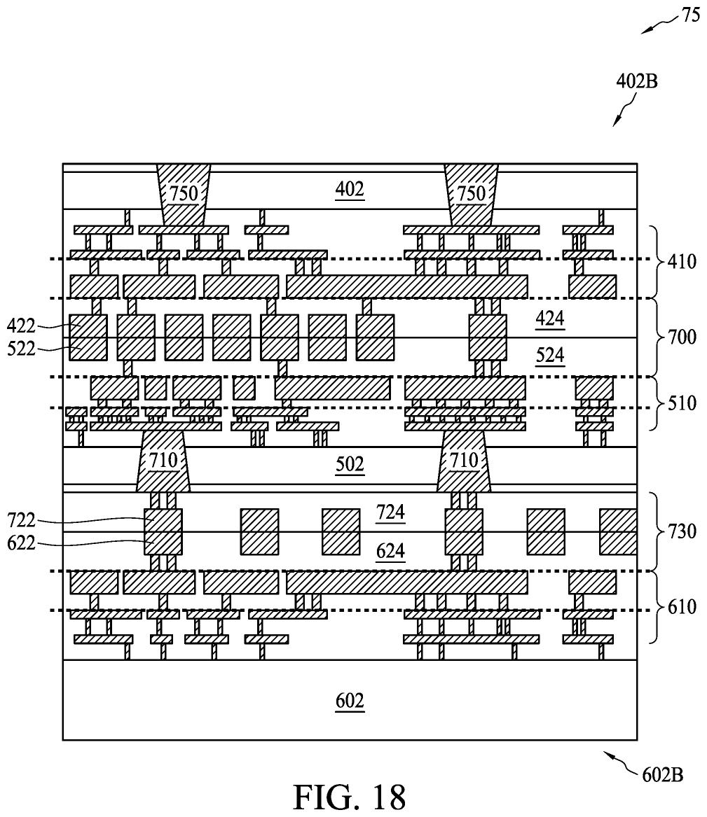

Referring to FIG. 18, a plurality of through-substrate vias 750 are formed. In some embodiments, operations for forming the through-substrate vias 750 may be similar to the operations for forming the through-substrate vias 310 and 312; therefore, such details are omitted for brevity. As shown in FIG. 18, the through-substrate via 750 is in contact with and electrically connected to the lowermost metallization layers 412t of the BEOL interconnect structure 410. In such embodiments, an electrical connection between the first side 402F (i.e., the front side) and the second side 402B (i.e., the back side) of the substrate 402 may be formed by the BEOL interconnect structure 410 and the through-substrate via 750.

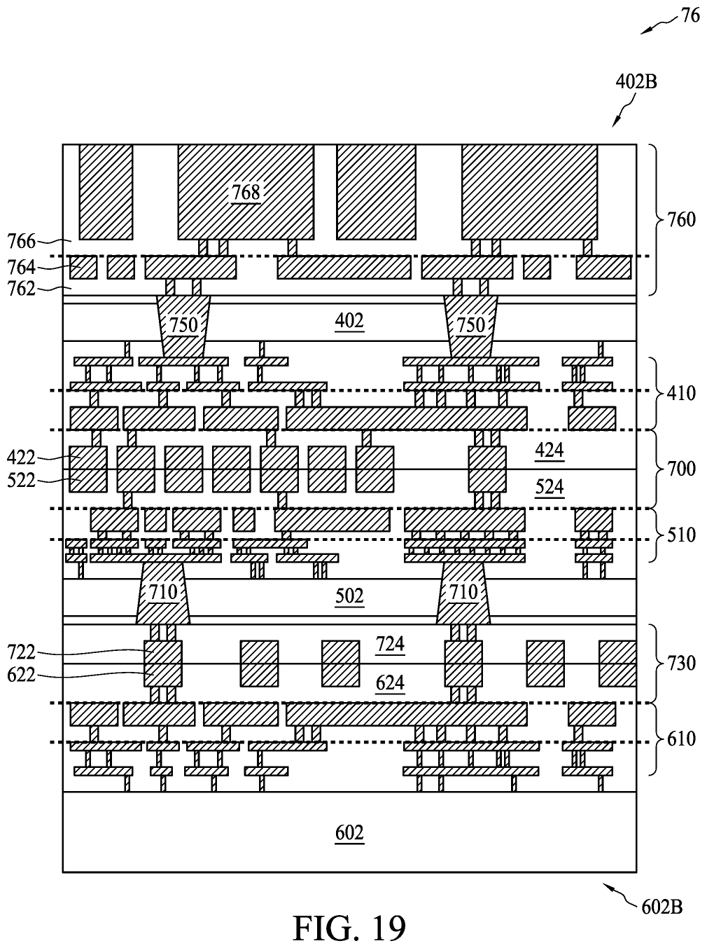

Referring to FIG. 19, in some embodiments, a redistribution layer (RDL) 760 is formed over the second side 402B of the substrate 402. In some embodiments, operations for forming the RDL 760 may be similar to the operations for forming the RDL 320; therefore, such details are omitted for brevity. As shown in FIG. 19, the RDL 760 may include a dielectric structure 762 that includes a plurality of dielectric layers, a metallization layer 764 in the multilayered dielectric structure 762, a dielectric structure 766 formed over the dielectric structure 762 and the metallization layers 764, and a plurality of conductive features 768 in the dielectric structure 766. As shown in FIG. 19, the conductive features 768 are coupled to and electrically connected to the metallization layer 764, and the metallization layer 764 is coupled and electrically connected to the through-substrate via 750. In some embodiments, a thickness of the conductive feature 768 is greater than a thickness of the metallization layer 764. In some embodiments, the thickness of the metallization layer 764 may be less than 10,000 angstroms, and the thickness of the conductive feature 768 may be greater than 15,000 angstroms. For example but not limited thereto, the thickness of the metallization layer 764 may be approximately 8,500 angstroms, and the thickness of the conductive feature 768 may be approximately 35,000 angstroms.

As shown in FIG. 19, the conductive features 768 are electrically connected to the BEOL interconnect structure 410 by the through-substrate vias 750. In some embodiments, the thickness of the conductive feature 768 is greater than the thicknesses of the metallization layers 764 of the RDL 760, the metallization layers 412t, 416t of the BEOL interconnect structure 410, the metallization layers 512t, 516t of the BEOL interconnect structure 510, and the metallization layers 612t, 616t of the BEOL interconnect structure 610. Further, the thickness of the conductive feature 768 may be greater than a thickness of the bonded metallization features 422 and 522, and greater than a thickness of the bonded metallization features 622 and 722.

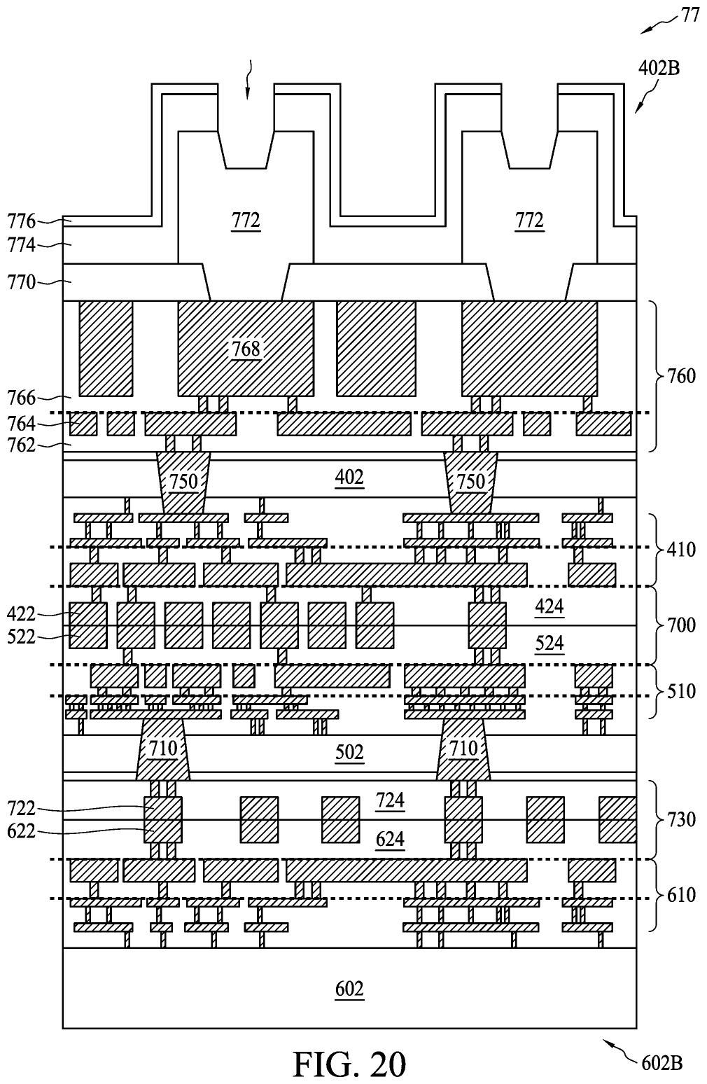

Referring to FIG. 20, in some embodiments, a dielectric structure 770 is formed over the RDL 760 on the back side 402B of the substrate 402. The dielectric structure 770 may be a multilayered dielectric structure. Materials for forming the dielectric structure 770 may be similar to the materials for forming the dielectric structure 330; therefore, such details are omitted for brevity. The dielectric structure 770 may be a passivation structure for protection against stress and/or moisture. After the forming of the dielectric structure 770, a plurality of pads 772 are formed in and over the dielectric structure 770. As shown in FIG. 20, the pads 772 are in contact with and electrically connected to the conductive features 768.

Sill referring to FIG. 20, in some embodiments, a dielectric layer 774 and a dielectric layer 776 are sequentially formed over the pads 772 and the dielectric structure 770. In some embodiments, the dielectric layers 774 and 776 are conformally formed over the pads 772 and the dielectric structure 770. In some embodiments, both the dielectric layer 774 and the dielectric layer 776 serve as passivation layers for protection against stress and/or moisture. In some embodiments, the dielectric layer 774 and the dielectric layer 776 may include different materials. Materials for forming the dielectric layers 774 and 776 may be similar to the materials for forming the dielectric layers 334 and 336; therefore, such details are omitted for brevity. In some embodiments, portions of the dielectric layers 774 and 776 are removed to form openings 777 exposing upper surfaces of the pads 772. In some embodiments, the dielectric layers 774 and 776 may remain over sidewalls and peripheral regions of the upper surfaces of the pads 772. The exposed upper surfaces of the pads 772 can be coupled to external elements.

Accordingly, a semiconductor package structure 77 is obtained. The semiconductor package structure 77 includes the conductive features 768 disposed between the pads 772 and the through-substrate vias 750. Further, the pads 772 are electrically connected to the through-substrate vias 750 by the conductive features 768 in the RDL 760. In some embodiments, communications between external elements and the substrates 402, 502 and 602 are enabled. In some embodiments, the conductive features 768 of the RDL 760 over the back side 402B of the substrate 402 is thick enough to reduce sheet resistance and prevent IR drop. Further, because the thick conductive features 768 are disposed on the second side 402B (i.e., the back side) of the substrate 402, warpage effect on the devices over the first side 402F (i.e., the front side) of the substrate 402 is mitigated. Thus, negative effect on to a bonding performance of the bonded structures 700 and 730 of the semiconductor package structure 77 is mitigated.

Referring to FIG. 21, a method for forming a semiconductor package structure 80 is provided. While the disclosed method 80 is illustrated and described herein as a series of acts or operations, it will be appreciated that an order of the illustrated acts or operations is not to be interpreted in a limiting sense. For example, some operations may occur in different orders and/or concurrently with other acts or operations apart from those illustrated and/or described herein. In addition, not all illustrated operations may be required to implement one or more aspects or embodiments of the method disclosed herein. Further, one or more of the operations depicted herein may be carried out in one or more separate operations and/or phases.

In operation 801, a first semiconductor component and a second semiconductor component are received. FIGS. 1A and 1B illustrate cross-sectional views of the semiconductor components 10 and 20 in accordance with some embodiments corresponding to operation 801. As described above, the first semiconductor component 10 includes a first substrate 102, a first BEOL interconnect structure 110 and a first bonding layer 120, and the second semiconductor component 20 include a second substrate 202, a second BEOL interconnect structure 210 and a second bonding layer 220. As mentioned above, the first substrate 102 of the first semiconductor component 10 has a first side 102F where microelectronic elements 104 are formed and a second side 102B opposite to the first side 102F, and the first BEOL interconnect structure 110 and the first bonding layer 120 are disposed over the first side 102F. The second substrate 202 of the second semiconductor component 20 has a first side 202F where microelectronic elements 204 are formed and a second side 202B opposite to the first side 202F, and the second BEOL interconnect structure 210 and the second bonding layer 220 are disposed over the first side 202F.

In operation 802, the first bonding layer 120 of the first semiconductor component 10 and the second bonding layer 220 of the second semiconductor component 20 are bonded to form a first bonded structure 300 between the first BEOL interconnect structure 110 and the second BEOL interconnect structure 210. FIG. 2 illustrates a cross-sectional view of an intermediate semiconductor package structure 30 in accordance with some embodiments corresponding to operation 802.

In operation 803, a through-substrate via 310 is formed in the first substrate 102. As FIG. 3 illustrates a cross-sectional view of an intermediate semiconductor package structure 31 in accordance with to some embodiments corresponding to operation 803. As shown in FIG. 3, the through-substrate via 310 penetrates the first substrate 102 from the second side 102B to the first side 102F.

In operation 804, a first dielectric structure 322 is formed over the through-substrate vias 310. In operation 805, a metallization layer 324 is formed in the first dielectric structure 322. In operation 806, a second dielectric structure 326 is formed over the metallization layer 324. In operation 807, a conductive feature 328 is formed in the second dielectric structure 326. FIGS. 4 to 9 illustrate cross-sectional views of an intermediate semiconductor package structure 32 in accordance with some embodiments corresponding to operations 804 to 807. In accordance with operations 804 to 807, an RDL 320 is formed over the second side 102B of the substrate 102 of the intermediate semiconductor package structure 32.

In operation 808, a pad 332 is formed over the RDL 320. In some embodiments, the pad 332 is formed over the conductive feature 328. FIG. 10 illustrates a cross-sectional view of a semiconductor package structure 33 in accordance with some embodiments corresponding to operation 808.

Referring to FIG. 22, a method for forming a semiconductor package structure 90 is provided. While the disclosed method 90 is illustrated and described herein as a series of acts or operations, it will be appreciated that an order of the illustrated acts or operations is not to be interpreted in a limiting sense. For example, some operations may occur in different orders and/or concurrently with other acts or operations apart from those illustrated and/or described herein. In addition, not all illustrated operations may be required to implement one or more aspects or embodiments of the method disclosed herein. Further, one or more of the operations depicted herein may be carried out in one or more separate operations and/or phases.

In operation 901, a first semiconductor component and a second semiconductor component are received. FIGS. 11A and 11B illustrate cross-sectional views of semiconductor components 40 and 50 in accordance with some embodiments corresponding to operation 901. As described above, the first semiconductor component 40 includes a first substrate 402, a first BEOL interconnect structure 410 and a first bonding layer 420, and the second semiconductor component 50 includes a second substrate 502, a second BEOL interconnect structure 510 and a second bonding layer 520. As mentioned above, the first substrate 402 of the first semiconductor component 40 has a first side 402F where microelectronic elements are formed and a second side 402B opposite to the first side 402F, and the first BEOL interconnect structure 410 and the first bonding layer 420 are disposed over the first side 402F. The second substrate 502 of the second semiconductor component 50 has a first side 502F where microelectronic elements are formed and a second side 502B opposite to the first side 502F, and the second BEOL interconnect structure 510 and the second bonding layer 520 are disposed over the first side 502F.

In operation 902, the first bonding layer 420 of the first semiconductor component 40 and the second bonding layer 520 of the second semiconductor component 50 are bonded to form a first bonded structure 700 between the first BEOL interconnect structure 410 and the second BEOL interconnect structure 510. FIG. 12 illustrates a cross-sectional view of an intermediate semiconductor package structure 70 in accordance with some embodiments corresponding to operation 902.

In operation 903, a through-substrate via 710 is formed in the second substrate 502. FIG. 13 illustrates a cross-sectional view of an intermediate semiconductor package structure 71 in accordance with some embodiments corresponding to operation 903. As shown in FIG. 13, the through-substrate via 710 penetrates the second substrate 502 from the second side 502B to the first side 502F.

In operation 904, a third bonding layer 720 is formed over the through-substrate via 710. FIG. 14 illustrates a cross-sectional view of an intermediate semiconductor package structure 72 in accordance with some embodiments corresponding to operation 904. As shown in FIG. 14, the third bonding layer 720 is formed over the second side 502B of the second substrate 502 of the intermediate semiconductor package structure 72.

In operation 905, a third semiconductor component 60 is received. FIGS. 11C and 15 illustrates cross-sectional views of the third semiconductor component 60 in accordance with some embodiments corresponding to operation 905. As shown in FIGS. 11C and 15, the third semiconductor component 60 includes a third substrate 602, a third BEOL interconnect structure 610 and a fourth bonding layer 620. The third substrate 602 of the third semiconductor component 60 has a first side 602F where microelectronic elements are formed and a second side 602B opposite to the first side 602F, and the third BEOL interconnect structure 610 and the fourth bonding layer 620 are disposed over the first side 602F.

In operation 906, the fourth bonding layer 620 of the third semiconductor component 60 and the third bonding layer 720 of the intermediate semiconductor package structure 72 are bonded to form a second bonded structure 730 between the third BEOL interconnect structure 610 and the second substrate 502. FIG. 16 illustrates a cross-sectional view of an intermediate semiconductor package structure 73 in accordance with some embodiments corresponding to operation 906.

In operation 907, a through-substrate via 750 is formed in the first substrate 402. FIGS. 17 and 18 illustrate cross-sectional views of intermediate semiconductor package structures 74 and 75 in accordance with some embodiments corresponding to operation 907. As shown in FIG. 18, the through-substrate via 750 penetrates the first substrate 402 from the second side 402B to the first side 402F.

In operation 908, an RDL 760 is formed over the through-substrate via 750. FIG. 19 illustrates a cross-sectional view of an intermediate semiconductor package structure 76 in accordance with some embodiments corresponding to operations 908. As shown in FIG. 19, the RDL 760 is formed over the second side 402B of the first substrate 402 of the intermediate semiconductor package structure 76.

In operation 909, a pad 772 is formed over the RDL 760. In some embodiments, the pad 772 is formed over the conductive feature 768. FIG. 20 illustrates a cross-sectional view of a semiconductor package structure 77 in accordance with some embodiments corresponding to operation 909.

In accordance with some embodiments, the present disclosure provides semiconductor package structures and methods of forming the semiconductor package structures, particularly WoW structures. In some embodiments, the semiconductor package structure has a scheme including metal lines with thickness sufficient to reduce sheet resistance and to prevent IR drop. The scheme of the semiconductor package structure also helps to reduce warpage and thus results in improved bonding performance.

In some embodiments, a semiconductor package structure is provided. The semiconductor package structure includes a first semiconductor component, a second semiconductor component, a bonded structure, a first through-substrate via, a pad, and a conductive feature. The first semiconductor component includes a first substrate and a first interconnect structure. The first interconnect structure is disposed over a first side of the first substrate. The second semiconductor component includes a second substrate and a second interconnect structure. The first through-substrate via penetrates the first substrate from a second side to the first side. The second side is opposite to the first side. The pad is disposed over the second side of the first substrate. The conductive feature is disposed over the second side of the first substrate and between the first through-substrate via and the pad. The conductive feature electrically connects the first through-substrate via to the pad. The conductive feature is electrically connected to the first interconnect structure by the first through-substrate via.

In some embodiments, a semiconductor package structure is provided. The semiconductor package structure includes a first semiconductor component, a second semiconductor component, a third semiconductor component, a first bonded structure, a second bonded structure, a first through-substrate via, a pad, and a conductive feature. The first semiconductor component includes a first substrate and a first interconnect structure. The second semiconductor component includes a second substrate and a second interconnect structure. The third semiconductor component includes a third substrate and a third interconnect structure. The first bonded structure is disposed between the first interconnect structure and the second interconnect structure. The second bonded structure is disposed between the second substrate and the third interconnect structure. The first through-substrate via penetrates the first substrate and electrically connected to the first interconnect structure. The pad is disposed over the first substrate on a side opposite to the first interconnect structure. The conductive feature is disposed between the first through-substrate via and the pad. The conductive feature electrically connects the first through-substrate via to the pad. The conductive feature is electrically connected to the first interconnect structure by the first through-substrate via.

In some embodiments, a method for forming a semiconductor package structure is provided. The method includes following operations. A first semiconductor component and a second semiconductor component are received. The first semiconductor component includes a first substrate, a first interconnect structure and a first bonding layer. The second semiconductor component includes a second substrate, a second interconnect structure and a second bonding layer. The first bonding layer and the second bonding layer are bonded to form a first bonded structure between the first interconnect structure and the second interconnect structure. A first through-substrate via penetrating the first substrate is formed. A redistribution layer (RDL) is formed over the first through-substrate via. A pad is formed over the RDL.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package structure comprising:
a first semiconductor component having a first substrate and a first interconnect structure, wherein the first interconnect structure is disposed on a first side of the first substrate;
a second semiconductor component having a second substrate and a second interconnect structure;
a bonded structure between and bonded to the first interconnect structure and the second interconnect structure;
a first through-substrate via penetrating the first substrate from a second side to the first side, wherein the second side is opposite to the first side;
a pad disposed over the second side of the first substrate; and
a conductive feature disposed over the second side of the first substrate and between the first through-substrate via and the pad,
wherein the conductive feature electrically connects the first through-substrate via to the pad, and the conductive feature is electrically connected to the first interconnect structure by the first through-substrate via.

2. The semiconductor package structure of claim 1, wherein the bonded structure comprises:
a first dielectric layer;
a first metallization feature disposed in the first dielectric layer and electrically connected to the first interconnect structure;
a second dielectric layer; and
a second metallization feature disposed in the second dielectric layer and electrically connected to the second interconnect structure,
wherein the first dielectric layer is bonded to the second dielectric layer, and the first metallization feature is bonded to the second metallization feature.

3. The semiconductor package structure of claim 1, wherein each of the first interconnect structure and the second interconnect structure comprises an uppermost metallization layer, and a thickness of the conductive feature is greater than a thickness of the uppermost metallization layer of the first interconnect structure, and greater than a thickness of the uppermost metallization layer of the second interconnect structure.

4. The semiconductor package structure of claim 3, wherein the thickness of the conductive feature is greater a sum of the thickness of the uppermost metallization layer of the first interconnect structure and the thickness of the uppermost metallization layer of the second interconnect structure.

5. The semiconductor package structure of claim 1, wherein the first interconnect structure comprises a lowermost metallization layer coupled to the first through-substrate via.

6. The semiconductor package structure of claim 1, further comprising a second through-substrate via penetrating the first substrate from the second side to the first side, wherein the second through-substrate via is in contact with a dielectric layer of the first interconnect structure.

7. The semiconductor package structure of claim 1, further comprising a redistribution layer (RDL) disposed on the second side of the first substrate, wherein the RDL comprises:
at least a metallization layer; and
a top dielectric layer over the metallization layer,
wherein the conductive feature is disposed in the top dielectric layer and electrically connected to the metallization layer.

8. A semiconductor package structure comprising:
a first semiconductor component having a first substrate and a first interconnect structure;
a second semiconductor component having a second substrate and a second interconnect structure;
a third semiconductor component having a third substrate and a third interconnect structure;
a first bonded structure between the first interconnect structure and the second interconnect structure;
a second bonded structure between the second substrate and the third interconnect structure;
a first through-substrate via penetrating the first substrate and electrically connected to the first interconnect structure;
a pad disposed over the first substrate on a side opposite to the first interconnect structure; and
a conductive feature disposed between the first through-substrate via and the pad,
wherein the conductive feature electrically connects the first through-substrate via to the pad, and the conductive feature is electrically connected to the first interconnect structure by the first through-substrate via.

9. The semiconductor package structure of claim 8, wherein each of the first interconnect structure and the second interconnect structure comprises an uppermost metallization layer, and a thickness of the conductive feature is greater than a thickness of the uppermost metallization layer of the first interconnect structure and greater than a thickness of the uppermost metallization layer of the second interconnect structure.

10. The semiconductor package structure of claim 9, wherein the thickness of the conductive feature is greater a sum of the thickness of the uppermost metallization layer of the first interconnect structure and the thickness of the uppermost metallization layer of the second interconnect structure.

11. The semiconductor package structure of claim 8, further comprising a second through-substrate via penetrating second substrate, wherein the second through-substrate via electrically connects the second interconnect structure to the second bonded structure.

12. The semiconductor package structure of claim 8, further comprising a redistribution layer (RDL) disposed on the second side of the first substrate, wherein the RDL comprises:
at least a metallization layer; and
a top dielectric layer over the metallization layer,
wherein the conductive feature is disposed in the top dielectric layer and electrically connected to the metallization layer.

13. A method for forming a semiconductor package structure, comprising:
receiving a first semiconductor component having a first substrate, a first interconnect structure and a first bonding layer, and receiving a second semiconductor component having a second substrate, a second interconnect structure and a second bonding layer;
bonding the first bonding layer to the second bonding layer to form a first bonded structure between the first interconnect structure and the second interconnect structure;
forming a first through-substrate via penetrating the first substrate;
forming a redistribution layer (RDL) over the first through-substrate via; and
forming a pad over the RDL.

14. The method of claim 13, further comprising:
forming a second through-substrate via penetrating the second substrate; and
forming a third bonding layer over the second through-substrate via.

15. The method of claim 14, further comprising:
receiving a third semiconductor component having a third substrate, a third interconnect structure and a fourth bonding layer; and
bonding the third bonding layer to the fourth bonding layer to form a second bonded structure.

16. The method of claim 15, wherein the first through-substrate via is formed after the forming of the second bonded structure.

17. The method of claim 16, wherein the forming of the RDL comprises:
forming a first dielectric structure over the first through-substrate via;
forming a metallization layer in the first dielectric structure;
forming a second dielectric structure over the metallization layer; and
forming a conductive feature in the second dielectric structure.

18. The method of claim 13, wherein each of the first interconnect structure and the second interconnect structure comprises an uppermost metallization layer, and a thickness of the conductive feature is greater than a thickness of the uppermost metallization layer of the first interconnect structure and greater than a thickness of the uppermost metallization layer of the second interconnect structure.

19. The method of claim 18, wherein the thickness of the conductive feature is greater a sum of the thickness of the uppermost metallization layer of the first interconnect structure and the thickness of the uppermost metallization layer of the second interconnect structure.

20. The method of claim 13, wherein the forming of the pad comprises:
forming a passivation structure over the conductive feature; and
forming the pad in the passivation structure,
wherein a portion of the pad is exposed through the passivation structure.
